(19) United States
(12) Patent Application Publication
(10) Pub. No.: US 2025/0006680 A1
(43) Pub. Date: Jan. 2, 2025

(54) SOLDER ALLOY, SOLDER JOINT, AND SEMICONDUCTOR PACKAGE INCLUDING SOLDER JOINT

(71) Applicant: DUKSAN HI-METAL CO., LTD., Ulsan (KR)

(72) Inventors: Eun Kwang PARK, Ulsan (KR); Jun Hyung LEE, Ulsan (KR)

(73) Assignee: DUKSAN HI-METAL CO., LTD., Ulsan (KR)

(21) Appl. No.: 18/648,591

(22) Filed: Apr. 29, 2024

(30) Foreign Application Priority Data
Jun. 30, 2023 (KR) 10-2023-0084751

(51) Int. Cl. H01L 23/00; B23K 35/02; B23K 35/26; B23K 101/38; C22C 13/00

(52) U.S. Cl. CPC H01L 24/13; B23K 35/0244; B23K 35/262; C22C 13/00; H01L 24/05; H01L 24/16; B23K 2101/38; H01L 24/81; H01L 2224/05583; H01L 2224/05644; H01L 2224/05647; H01L 2224/05655; H01L 2224/13111; H01L 2224/13113; H01L 2224/13117; H01L 2224/13139; H01L 2224/13147; H01L 2224/13155; H01L 2224/13164; H01L 2224/16227; H01L 2224/81192; H01L 2224/81815; H01L 2924/01032; H01L 2924/1438; H01L 2924/1441; H01L 2924/1443

(57) ABSTRACT

One embodiment provides a solder alloy including Ag in a content of 2.7 wt % to 3.3 wt %. Cu in a content of 0.50 wt % to 0.75 wt %. Bi in a content of 0.8 wt % to 1.2 wt %. Ni in a content of 0.03 wt % to 0.10 wt %. Pd in a content of 0.01 wt % to 0.04 wt %, and a remainder of Sn and unavoidable impurities.

### CROSS-REFERENCE TO RELATED APPLICATION

This application claims priority to and the benefit of Korean Patent Application No. 10-2023-0084751, filed on Jun. 30, 2023 the disclosure of which is incorporated herein by reference in its entirety.

### BACKGROUND

### 1. Field of the Invention

The present invention relates to a solder alloy, a solder joint, and a semiconductor package including the solder joint.

### 2. Discussion of Related Art

Recently, as semiconductor technologies have developed, semiconductors have been used in various electronic devices. For example, semiconductors are used in electronic devices in various fields, such as small-sized cell phones, medium-sized tablets and computers, and large-sized vehicles. When the electronic devices are used for a long period of time, semiconductors may be exposed to harsh temperature change environments due to changes in external temperature or internal temperature of the devices. In addition, when the electronic devices are exposed to external shock, semiconductors may be damaged. Accordingly, semiconductors embedded inside the electronic devices simultaneously require physical properties such as shock resistance and thermal cycle reliability.

Meanwhile, as a method of joining electronic components such as semiconductor chips to a conductor pattern formed on an electronic circuit board such as a printed wiring board or a module board, there is a solder joining method using a solder alloy. Previously, lead-containing solder alloys were used, but recently, due to the rise of environmental issues, the use of lead-free solder alloys that do not include lead has become common. As lead-free solder alloys, ternary alloys (hereinafter referred to as SAC alloys) having a basic composition of tin (Sn), silver (Ag), and copper (Cu) are mainly used. Among the ternary alloys, a SAC alloy including Ag in a content of 3 wt %, Cu in a content of 0.5 wt % and a remainder of Sn (hereinafter SAC305) is mainly used. However, there has recently been a need to develop a solder alloy with improved thermal cycle reliability and impact resistance for application to various electronic devices.

### SUMMARY OF THE INVENTION

The present invention is directed to providing a solder alloy having improved tensile strength and wettability.

The present invention is also directed to providing a solder joint with improved thermal cycle reliability, drop resistance, and shear strength.

The present invention is also directed to providing an electronic semiconductor package with excellent durability.

According to an aspect of the present invention, there is provided an a solder alloy including Ag in a content of 2.7 wt % to 3.3 wt %, Cu in a content of 0.50 wt % to 0.75 wt %, Bi in a content of 0.8 wt % to 1.2 wt %, Ni in a content of 0.03 wt % to 0.10 wt %, Pd in a content of 0.01 wt % to 0.04 wt %, and remainders of Sn and unavoidable impurities.

The solder alloy may further include Ge in a content of 0.005 wt % to 0.010 wt %.

According to another aspect of the present invention, there is provided a solder ball including Ag in a content of 2.7 wt % to 3.3 wt %, Cu in a content of 0.50 wt % to 0.75 wt %, Bi in a content of 0.8 wt % to 1.2 wt %, Ni in a content of 0.03 wt % to 0.10 wt %, Pd in a content of 0.01 wt % to 0.04 wt %, and remainders of Sn and inevitable impurities.

The solder ball may further include Ge in a content of 0.005 wt % to 0.010 wt %.

The solder ball may have a particle diameter of 10 μm to 780 μm.

According to still another aspect of the present invention, there is provided a semiconductor package including a lower electronic component, an upper electronic component disposed on the lower electronic component, and a solder joint disposed between the lower electronic component and the upper electronic component and made of a solder alloy, wherein the solder alloy includes, Ag in a content of 2.7 wt % to 3.3 wt %, Cu in a content of 0.50 wt % to 0.75 wt %, Bi in a content of 0.8 wt % to 1.2 wt %, Ni in a content of 0.03 wt % to 0.10 wt %, Pd in a content of 0.01 wt % to 0.04 wt %, and remainders of Sn and unavoidable impurities.

The lower electronic component may include a substrate and a substrate electrode disposed on the substrate, and the upper electronic component may include a base layer and a semiconductor electrode disposed on the base layer.

The substrate electrode and the semiconductor electrode may include an electrode layer including Cu, a first plating layer disposed on the electrode layer and including Ni, and a second plating layer disposed on the first plating layer and including Au.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic view illustrating a semiconductor package of one embodiment; and

FIG. 2 is an enlarged view of a portion of the semiconductor package of one embodiment.

### DETAILED DESCRIPTION OF EXEMPLARY EMBODIMENTS

Since the present invention can undergo various transformations and have various embodiments, specific embodiments will be illustrated in the drawings and described in detail in the detailed description. However, it should be understood that this is not intended to limit the present invention to specific embodiments, but that it includes all transformations, equivalents, and substitutes included in the spirit and scope of the disclosure.

In this specification, when a component (or a region, a layer, a portion, etc.) is referred to as being “on,” “connected to,” or “coupled to” another component, it means that the component may be directly disposed on/connected to/coupled to the other component or that a third component may be disposed therebetween.

Meanwhile, in this application, “directly disposed” may indicate that there is no layer, film, region, plate or the like added between a portion of a layer, a film, a region, a plate or the like and other portions. For example, “directly disposed” may indicate disposition without additional members such as an adhesive member between two layers or two members.

Like reference numerals designate like components. Additionally, in the drawings, the thicknesses, proportions, and dimensions of components are exaggerated for effective description of technical content.

The term “and/or” includes all of one or more combinations defined by listed components.

The terms “first,” “second,” and the like may be simply used for description of various constituent elements, but their meanings may not be limited to restricted meanings. The above terms are used only for distinguishing one constituent element from other constituent elements. For example, a first constituent element may be referred to as a second constituent element, and similarly, a second constituent element may be referred to as a first constituent element without departing from the scope of the present invention. An expression of a singular number includes an expression of the plural number unless clearly indicated otherwise.

In addition, terms such as “below,” “lower,” “on,” and “upper” are used to describe a relationship of configurations shown in the drawing. These terms are described as a relative concept based on an orientation shown in the drawing. In this specification, when a member is referred to as being “on” another member, it can be disposed above or below the other member.

Unless otherwise defined, all terms (including technical and scientific terms) used herein have the same meaning as commonly understood by those skilled in the art to which the present invention pertains. In addition, terms as defined in a commonly used dictionary should be construed as having the same meaning as in an associated technical context, and unless explicitly defined in the description, the terms are not ideally or excessively construed as having formal meanings.

The term “comprise” or “has” is used to specify existence of a feature, a number, a process, an operation, a constituent element, a part, or a combination thereof, and it will be understood that the possibility of the existence or addition of one or more other features or numbers, processes, operations, constituent elements, parts, or combinations thereof is not excluded in advance.

When a certain embodiment may be implemented differently, a specific process order may be performed differently from the described order. For example, two consecutively described processes may be performed substantially at the same time or may be performed in an order opposite to the described order.

In this specification, “%” refers to “wt %” when not specifically defined. In addition, in this specification, a melting point is a solidus temperature or a liquidus temperature.

In this specification, “inevitable impurities” may be impurities that are not intentionally added but are added unintentionally during a manufacturing process and may be impurities included in a content of less than about 0.001 wt % by weight.

Hereinafter, a solder alloy, a solder joint, and a semiconductor package including the solder joint according to one embodiment will be described.

### 1. Solder Joint and Semiconductor Package

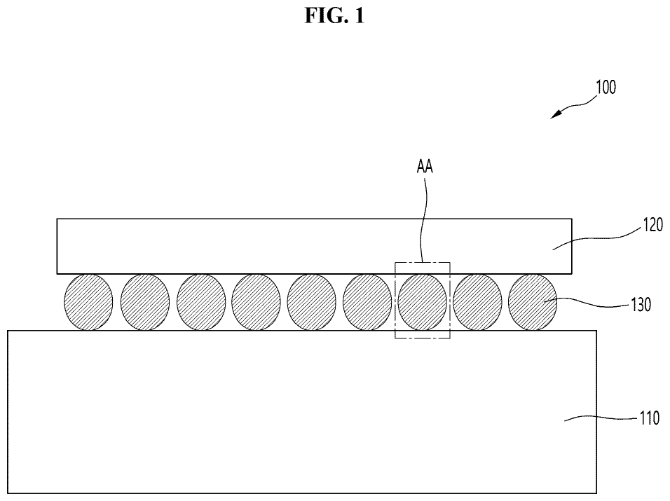

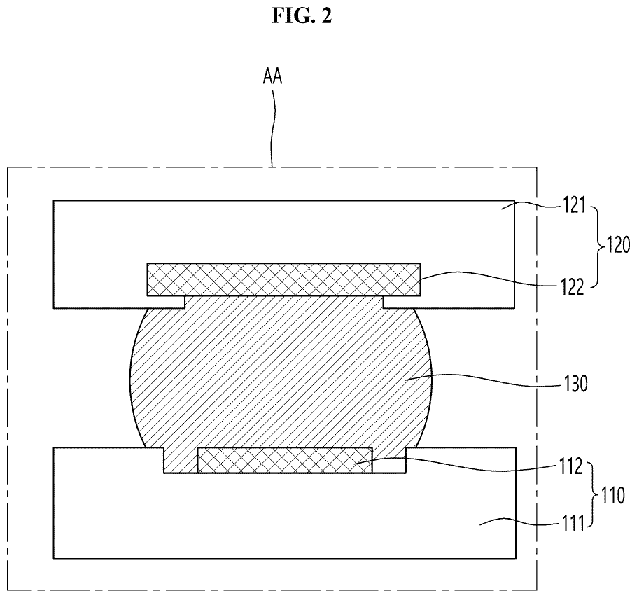

FIG. 1 is a schematic view illustrating a semiconductor package of one embodiment. FIG. 2 is an enlarged view of a portion of the semiconductor package of one embodiment. FIG. 2 is an enlarged view of a portion corresponding to AA′ of FIG. 1.

Referring to FIGS. 1 and 2, a semiconductor package 100 of one embodiment includes a lower electronic component 110, an upper electronic component 120, and a solder joint 130. The solder joint 130 may be disposed between the lower electronic component 110 and the upper electronic component 120.

The lower electronic component 110 according to one embodiment may be a printed circuit board (PCB) or a flexible printed circuit board (FPCB). In one embodiment, the lower electronic component 110 may include a lower substrate 111 and a plurality of substrate electrodes 112 disposed on the lower substrate 111. The substrate electrodes 112 may be disposed to be spaced apart from each other.

Each substrate electrode 112 may be a copper (Cu) pad treated with an organic solderability preservative (OSP) or a copper pad including a plating layer. The plating layer may be closer to the solder joint 130 than the copper pad. The plating layer may include at least one selected from Ni and Au. Specifically, the plating layer may be an electrolytic nickel layer or an electroless nickel layer including phosphorus (P). However, this is merely an example, and a type of the substrate electrode 112 is not limited thereto.

Meanwhile, in one embodiment, the plating layer may have a single layer structure or may include a plurality of sub-plating layers. The sub-plating layers may include a first sub-plating layer adjacent to the substrate electrode 112 and a second sub-plating layer disposed on the first sub plating layer. The first sub-plating layer may include Ni, and the second sub-plating layer may include a Au layer. However, this is merely an example, and a type of the substrate electrode 112 is not limited thereto.

The upper electronic component 120 according to one embodiment may be a semiconductor chip. The upper electronic component 120 according to one embodiment may include a flash memory, a phase-change random access memory (RAM) (PRAM), a resistive RAM (RRAM), a ferroelectric RAM (FeRAM), or a solid magnetic RAM (MRAM). However, this is merely an example, and a type of the upper electronic component 120 is not limited thereto.

The upper electronic component 120 may be spaced apart from the lower electronic component 110 in a thickness direction with the solder joint 130 interposed therebetween. The upper electronic component 120 may be electrically connected to the lower electronic component 110 through the solder joint 130.

The upper electronic component 120 according to one embodiment may include a base layer 121 and a semiconductor electrode 122 disposed on the base layer 121. The semiconductor electrode 122 may be electrically connected to the substrate electrode 112 through the solder joint 130.

Meanwhile, the upper electronic component 120 according to one embodiment may be provided as a single semiconductor chip or may be provided as a stack of a plurality of semiconductor chips. In addition, the upper electronic component 120 may be an integrated semiconductor chip or a type in which a semiconductor chip is mounted on a semiconductor substrate and is encapsulated with an encapsulation material.

The solder joint 130 according to one embodiment may be disposed between the lower electronic component 110 and the upper electronic component 120. The solder joint 130 may electrically connect the lower electronic component 110 and the upper electronic component 120. The solder joint 130 of one embodiment may be made of a solder alloy of one embodiment. Specifically, the solder joint 130 of one embodiment may be a result of a soldering process using a solder alloy.

Meanwhile, the solder alloy of one embodiment may include Ag, Cu, Bi, Ni, and a remainder of Sn. The solder joint 130 made of the solder alloy of one embodiment may simultaneously exhibit excellent thermal cycle reliability and excellent shock resistance. Accordingly, the lower electronic component 110 of one embodiment may exhibit excellent durability against temperature changes and external shock.

Hereinafter, the solder alloy will be described in detail.

### 2. Composition of Solder Alloy

One embodiment provides a solder ally including Ag in a content of 2.7 wt % to 3.3 wt %, Cu in a content of 0.50 wt % to 0.75 wt %, Bi in a content of 0.8 wt % to 1.2 wt %, Ni in a content of 0.03 wt % to 0.10 wt %, Pd in a content of 0.01 wt % to 0.04 wt %, and a remainder of Sn and unavoidable impurities. Meanwhile, the solder alloy of one embodiment may further include Ge. Hereinafter, elements constituting a composition of the solder alloy and contents thereof will be described.

### 2.1 Ag (Silver)

A solder alloy including Ag may provide mechanical strength to a solder joint by precipitating a Ag₃Sn compound in the solder joint. For example, a solder alloy including Ag in a content of 2.7 wt % to 3.3 wt % may improve the mechanical strength of a solder joint.

On the other hand, in a solder joint made of a solder alloy including Ag in a content of less than 2.7 wt %, since an amount of precipitated Ag₃Sn is insufficient, an effect of improving the strength and thermal cycling reliability of the solder joint due to a precipitate may be insignificant. In a solder joint made of a solder alloy including Ag in a content of more than 3.3 wt %, since an amount of precipitated Ag₃Sn excessively increases, ductility and drop resistance may degrade.

Meanwhile, Ag having a content of more than 1.3 wt % increases hardness, which has a problem in that a shock absorption function of a solder joint is lowered. Accordingly, the solder joint made of the solder alloy including Ag in a content of more than 1.3 wt % has a problem in that delamination between targets to be jointed easily occurs.

### 2.2 Copper (Cu)

A solder alloy including Cu may improve the joint strength of a solder joint by forming a Cu₆Sn₅ precipitate in the solder joint. For example, the solder alloy may include Cu in a content of 0.50 wt % to 0.75 wt %.

In a solder joint made of a solder alloy including Cu in a content of less than 0.50 wt %, since the precipitation of Cu₆Sn₅ is insufficient, an effect of improving the strength and thermal cycle reliability of the solder joint due to a precipitate may be insignificant. In a solder alloy including Cu in a content of more than 0.75 wt %, the wettability of a molten solder may degrade and voids in a solder joint may increase. Accordingly, the shear strength and thermal cycle reliability of a solder joint made of the solder alloy including Cu in a content of more than 0.75 wt % may degrade.

### 2.3 Bismuth (Bi)

Bi may solid-solution-strengthen a solder alloy to improve the strength and thermal cycle reliability of a solder joint. Specifically, Bi may substitute for a portion in a Sn matrix of the solder alloy to densify a Sn crystal lattice. Accordingly, a solder joint made of the solder alloy including Bi may exhibit an excellent crack propagation suppression effect and thus may exhibit excellent thermal cycle reliability.

For example, a solder joint made of a solder alloy including Bi in a content of 0.8% to 1.2% may exhibit excellent thermal cycle reliability because a Sn matrix is solid-solution-strengthened by Bi. In a solder joint made of a solder alloy including Bi in a content of less than 0.8 wt %, a solid solution strengthening effect by Bi is insignificant, and thus thermal cycle reliability is not improved. In a solder joint made of a solder alloy including Bi in a content of more than 2.5 wt %, strength may excessively increase, and thus drop resistance may degrade.

2.4 Nickel (Ni)

Ni may refine a crystal of a solder alloy to improve the strength of a solder joint. Specifically, a solder alloy may include Ni, and thus (Cu,Ni)₆Sn₅ may be formed in the solder alloy. (Cu, Ni)₆Sn₅ may have a slower crystal growth rate than Cu₆Sn₅, and thus as a ratio of (Cu,Ni)₆Sn₅ in the solder alloy increases, a precipitate crystal may be refined.

For example, a solder alloy including Ni in a content of 0.03 wt % to 0.10 wt % may include (Cu, Ni)₆Sn₅ to form a solder joint with improved thermal cycle reliability and drop resistance. In a solder alloy including Ni in a content of less than 0.03 wt %, Cu₆Sn₅ may be precipitated predominantly over (Cu,Ni)₆Sn₅, and thus crystal refinement may be insufficient. As a result, a solder joint made of the solder alloy including Ni in a content of less than 0.03 wt % may have degraded drop resistance. In a solder alloy including Ni in a content of more than 0.10 wt %, Ni₃Sn₄ with a high melting point may be precipitated, thereby increasing the viscosity of a molten solder. Specifically, Ni₃Sn₄ may have a melting point of 800° C. and may remain in the form of a precipitate in the molten solder, thereby increasing the viscosity of the molten solder. Accordingly, the solder alloy including Ni in a content of more than 0.10 wt % may have high viscosity, and thus there may be a limitation in manufacturing solder balls.

During a process of soldering a solder alloy on an electroless Ni-plated electrode, Ni may leach into the solder alloy from the electroless Ni plating electrode. The leaching of Ni may form a phosphorus (P)-rich layer at an interface between an electroless Ni-plated electrode and the solder alloy. The P-rich layer is brittle and thus has a problem of degrading the shear strength of the solder joint. Therefore, when a process of soldering a solder alloy on an electroless Ni-plated electrode is performed, it is necessary to suppress the leaching of Ni.

The solder alloy of one embodiment may include Ni in a content of 0.03 wt % to 0.10 wt %, thereby suppressing Ni from leaching in a direction from the electroless Ni-plated-electrode to the solder alloy. The solder alloy including Ni in a content of less than 0.03 wt % may have a limited effect in suppressing the leaching of Ni and thus cannot prevent the degradation of shear strength of the solder joint. The solder alloy including Ni in a content of more than 0.10 wt % may induce precipitation of brittle Ni₃Sn₄ at an interface between an electrode and the solder alloy, thereby degrading the drop resistance of a solder joint.

Meanwhile, during a process of soldering a solder alloy on a Ni/Au-plated electrode, Ni may be leached into the solder alloy from the Ni/Au-plated electrode. The leaching of Ni has a problem of increasing a thickness of an intermetallic compound (IMC) layer including Ni at an interface between the Ni/Au-plated electrode and the solder alloy. An increase in thickness of the IMC layer has a problem of degrading the drop resistance of the solder joint. Therefore, when a process of soldering a solder alloy on a Ni/Au electrode is performed, it is necessary to suppress the leaching of Ni.

When the solder alloy including Ni is soldered to the Ni/Au electrode, the solder alloy including Ni in a content of 0.03 wt % to 0.10 wt % may minimize an amount of Ni leached from the Ni/Au electrode due to the leaching of Ni, and thus a thickness of an IMC layer at an interface between a solder joint and an electrode may be reduced, thereby exhibiting excellent drop resistance.

In the solder alloy including Ni in a content of less than 0.03 wt %, an amount of precipitated Ni may not be suppressed, and as a result, a thickness of an IMC layer may be increased, which may degrade the drop resistance of a solder joint. The solder alloy including Ni in a content of more than 0.10 wt % may induce precipitation of brittle Ni₃Sn₄ at an interface between an electrode and the solder alloy, which may degrade the drop resistance of a solder joint.

### 2.5 Pd

Pd may suppress the growth of Cu₃Sn in a solder alloy. Cu₃Sn has a graphite structure and tends to facilitate crack propagation due to thermal fatigue in a solder. That is, a solder alloy of one embodiment including Pd may suppress the formation and growth of a Cu₃Sn compound having a graphite structure, thereby forming a solder joint that exhibits excellent thermal cycle reliability.

Pd in a solder alloy combines with an a-Sn phase, which is a low-temperature phase formed under experimental conditions of a temperature ranging from −40° C. to 125° C., and a β-Sn phase previously formed in a matrix, thereby producing a PdSn₄ compound. PdSn₄ may have a rod-shaped structure, may be present at a phase boundary (specifically, a Ag₃Sn interface) for phase equilibrium, and may suppress cracks generated by thermal fatigue from propagating at the phase boundary. As a result, a solder joint made of the solder alloy including Pd may exhibit excellent thermal cycle reliability.

For example, the solder alloy of one embodiment may include Pd in a content of 0.01 wt % to 0.04 wt %. In a solder alloy including Pd in a content of less than 0.01 wt %, a PdSn₄ formation effect and a Cu₃Sn formation suppressing effect are insignificant, and thus there is a limitation in improving the thermal cycle reliability of a solder joint. In addition, in a solder alloy including Pd in a content of more than 0.04 wt %, coarse crystals may be formed due to the agglomeration of particles (Ostwald ripening), or an excessive amount of PdSn₄ may be produced, which may degrade the shear strength and thermal cycle reliability of a solder joint.

### 2.6 Remainder of Sn

The remainder of a solder alloy in one embodiment may be Sn and unavoidable impurities. Even including the unavoidable impurities, the solder alloy of one embodiment maintains the same effects as described above.

The solder alloy according to one embodiment may simultaneously exhibit tensile strength and wettability. In addition, the solder alloy of one embodiment may include Sn, Ag, Cu, Bi, Ni, and Pd in an optimal ratio, thereby forming a solder joint that simultaneously exhibits excellent drop resistance and excellent thermal cycle reliability.

### 3. Method of Preparing Solder Alloy

A solder alloy of one embodiment is prepared by melting and mixing raw metals, and a preparation method is not limited.

### 4. Processing of Solder Alloy

A solder alloy may be processed into various shapes prior to a soldering process.

### 4.1 Solder Ball

The solder alloy of one embodiment may be used as a material for a solder ball. The solder ball may be prepared to have a certain size by i) melting the solder alloy of one embodiment into a molten metal, ii) injecting a master alloy into the molten metal, iii) induction-heating a mixture of the solder alloy and the master alloy, and iv) allowing the induction-heated mixture of the solder alloy and the master alloy to pass through an orifice hole. For example, a particle diameter of the solder ball may be in a range of 10 μm to 780 μm. Preferably, the particle diameter of the solder ball may be in a range of 200 μm to 500 μm. However, this is merely an example and the embodiment is not limited thereto.

Meanwhile, the above-described method of preparing a solder ball is merely exemplary and the present invention is not limited thereto, and the solder ball may be prepared through a method known in the art, including a gas atomization method.

### 4.2 Solder Preform

The solder alloy according to the present invention may be used as a solder preform. The preform may have the form of a washer, a ring, a pellet, a disc, a ribbon, a wire, and the like.

### 4.3 Solder Paste

The solder alloy according to the present invention may be used as a solder paste. The solder paste may be prepared to have a paste phase made by mixing a solder alloy powder with a small amount of flux. The solder alloy according to the present invention may be used as a solder paste in a process of mounting electronic components on a PCB through a reflow soldering method. The flux used in the solder paste may be either a water-soluble flux or a water-insoluble flux. For example, the flux used in the solder paste may be a rosin-based flux which is a rosin-based water-insoluble flux.

Hereinafter, the present invention will be described in more detail through specific manufacturing methods, examples, and comparative examples. The following examples are merely examples to help the understanding of the present invention, and the scope of the present invention is not limited thereto.

### [Manufacturing Examples]

### (Method of Manufacturing Solder Alloy Specimen)

A solder alloy, a solder joint, and a semiconductor package according to one embodiment of the present invention may be manufactured, for example, as follows. However, the present invention is not limited thereto.

Solder alloy specimens of examples and comparative examples were manufactured by preparing Sn, Ag, Cu, Bi, and Ni into master alloys of Sn—Ag, Sn—Cu, Sn—Bi, and Sn—Ni, and then putting the prepared master alloys into a high-frequency vacuum induction furnace. In this case, a ratio between individual master alloy metals in the master alloys may be changed according to a composition of a solder alloy specimen to be finally manufactured.

The solder alloy may be prepared by performing purging for about 20 minutes under conditions of a pressure of 750 torr to 760 torr in a nitrogen atmosphere in a state in which a vacuum degree of a high-frequency vacuum induction furnace is maintained at a pressure of 3.0×10⁻² torr to 6.0×10⁻² torr. During preparation of the solder alloy, a temperature profile was i) raised from 25° C. to 700° C. for 5 minutes, ii) maintained at 700° C. for 5 minutes, iii) raised from 700° C. to 1,100° C. for 4 minutes, and iv) maintained at 1,100° C. for 10 minutes.

### (Method of Manufacturing Semiconductor Package Specimen)

Solder balls prepared using the solder alloy specimens of the examples and comparative examples were each mounted on an OSP-treated Cu electrode of a PCB. A reflow process was performed to join the mounted solder ball and the PCB. During the reflow process, a water-soluble type flux was used. The reflow process was performed at a peak temperature of 240° C. for a dwell time of 50 seconds based on a temperature of 220° C. in an atmosphere of 3,000 ppm O₂. Afterwards, the PCB to which the solder ball was bonded was bonded to a semiconductor chip including an OSP-treated Cu electrode under the same process conditions, thereby manufacturing semiconductor package specimens. Meanwhile, in manufacturing the specimen, a PCB with a thickness of 0.8 mm, a Cu electrode with a diameter of 360 μm, an SR open of 280 μm, and a solder ball with a diameter of 300 μm were used.

### [Experimental Example]

### (Solder Alloy Property Evaluation Method and Evaluation Criteria)

### 1. Tensile Strength

By using a tensile strength tester (ST-1003 manufactured by SALT Co., Ltd.), tensile strength (MPa) was measured at a stroke speed of 2.0 mm/min. When the tensile strength was 30 MPa or more, it was determined as “o,” and when the tensile strength was less than 30 MPa, it was determined as “X.”

### 2. Wettability

Wettability was measured on the semiconductor package specimen using a stereoscopic microscope, and a wet diffusion area of the specimen was measured according to JIS Z-3197. When the wet diffusion rate was 0.20 mm² or more, it was determined as “o,” and when the wet diffusion rate was less than 0.20 mm², it was determined as “X.”

### (Semiconductor Package Property Evaluation Method and Evaluation Criteria)

### 1. Shear Strength Evaluation Method and Evaluation Criteria

A shear strength (gf) of the semiconductor package specimen was measured under conditions of 300 μm/see using a shear strength measuring device (SERIES 4000 manufactured by Nordson Dage Corporation). When the shear strength was 350 gf or more, it was determined as “o,” and when the shear strength was less than 350 gf, it was determined as “X.”

### 2. Thermal Cycle Reliability Test

In order to measure the thermal cycle properties of the semiconductor package specimen, a thermal cycle reliability test was performed under conditions of a temperature of −40° C. to 125° C. according to the JEDS22-A104-B standard. By using a thermal shock apparatus (TSA101LA manufactured by ESPEC Corporation), one cycle, in which, after the semiconductor package specimen was rested at a temperature of 125° C. for 10 minutes, the temperature was changed to −40° C. and maintained for 10 minutes, was performed, and then the number of cycles at which the specimen was destructed was measured. By measuring resistance whenever a cycle was completed, a point at which a short circuit occurred was used as a criterion at which the specimen was destructed. When the number of cycles at which an electronic component specimen was destructed was 4,000 or more, it was determined as “o,” and when the number of cycles was less than 4000, it was determined as “X.”

### 3. Drop Resistance Test

The drop resistance of the semiconductor package specimens was tested according to the JESD22-B111 standard. An impulse of a gravitational acceleration of 1,500 G and a time of 0.5 ms were applied to the semiconductor package specimen to measure the number of drops at which the semiconductor package specimen was destructed. When a drop impact resistance value of 3 drop evaluations among 5 drop evaluations increased by 10% or more as compared to an initial drop impact resistance, it was evaluated that the semiconductor package specimen was destructed. When the number of drops at which a first destruction of the electronic component specimen occurred was 30 or more, it was determined as “o,” and when the number of drops was less than 30, it was determined as “X.”

### (Results of Evaluating Characteristics of Solder Alloy and Semiconductor Package)

Composition ratio and property evaluation results of the solder alloy specimen of each of Examples 1 to 15 and Comparative Examples 1 to 13 are shown in Table 1. When an evaluation could not be performed because it was impossible to manufacture a solder ball specimen and a semiconductor package specimen, it was marked as “N.”

TABLE 1

| | | | | | | | | Thermal | | | |
|---|---|---|---|---|---|---|---|---|---|---|---|
| | | | | | | | Drop | cycle | Tensile | Shear | |
| Specification | Ag | Cu | Bi | Ni | Pd | Sn | resistance | reliability | strength | strength | Wettability |
| Example 1 | 3.0 | 0.7 | 0.8 | 0.05 | 0.025 | Remainder | O | O | O | O | O |
| Example 2 | 3.0 | 0.7 | 0.9 | 0.05 | 0.025 | Remainder | O | O | O | O | O |
| Example 3 | 3.0 | 0.7 | 1.0 | 0.05 | 0.025 | Remainder | O | O | O | O | O |
| Example 4 | 3.0 | 0.7 | 1.1 | 0.05 | 0.025 | Remainder | O | O | O | O | O |
| Example 5 | 3.0 | 0.7 | 1.2 | 0.05 | 0.025 | Remainder | O | O | O | O | O |
| Example 6 | 3.0 | 0.7 | 1.0 | 0.03 | 0.025 | Remainder | O | O | O | O | O |
| Example 7 | 3.0 | 0.7 | 1.0 | 0.10 | 0.025 | Remainder | O | O | O | O | O |
| Example 8 | 3.0 | 0.7 | 1.0 | 0.05 | 0.025 | Remainder | O | O | O | O | O |
| Example 9 | 3.0 | 0.7 | 1.0 | 0.05 | 0.025 | Remainder | O | O | O | O | O |
| Example 10 | 1.3 | 0.7 | 1.0 | 0.05 | 0.010 | Remainder | O | O | O | O | O |
| Example 11 | 1.0 | 0.5 | 1.0 | 0.03 | 0.040 | Remainder | O | O | O | O | O |
| Example 12 | 2.8 | 0.7 | 1.0 | 0.07 | 0.030 | Remainder | O | O | O | O | O |
| Example 13 | 3.2 | 0.7 | 0.9 | 0.05 | 0.020 | Remainder | O | O | O | O | O |
| Example 14 | 3.1 | 0.6 | 0.8 | 0.06 | 0.040 | Remainder | O | O | O | O | O |
| Example 15 | 3.2 | 0.5 | 1.2 | 0.08 | 0.020 | Remainder | O | O | O | O | O |
| Comparative | 1.2 | 0.5 | — | — | — | Remainder | N | N | X | N | X |
| Example 1 | | | | | | | | | | | |
| Comparative | 2.0 | 0.7 | 1.5 | 0.05 | — | Remainder | X | O | O | O | O |
| Example 2 | | | | | | | | | | | |
| Comparative | 3.0 | 0.7 | 1.0 | — | | Remainder | X | O | O | O | O |
| Example 3 | | | | | | | | | | | |
| Comparative | 3.0 | 0.7 | 1.0 | — | 0.025 | Remainder | X | O | O | O | O |
| Example 4 | | | | | | | | | | | |
| Comparative | 3.0 | 0.7 | 1.0 | 0.05 | — | Remainder | X | O | O | O | O |
| Example 5 | | | | | | | | | | | |
| Comparative | 1.0 | 0.7 | 1.0 | 0.05 | 0.025 | Remainder | O | X | X | O | O |
| Example 6 | | | | | | | | | | | |
| Comparative | 2.0 | 0.7 | 1.0 | 0.05 | 0.025 | Remainder | O | X | O | O | O |
| Example 7 | | | | | | | | | | | |
| Comparative | 3.0 | 0.7 | 0.6 | 0.05 | 0.025 | Remainder | O | X | O | O | O |
| Example 8 | | | | | | | | | | | |
| Comparative | 3.0 | 0.7 | 1.5 | 0.05 | 0.025 | Remainder | X | O | O | X | O |
| Example 9 | | | | | | | | | | | |
| Comparative | 3.0 | 0.7 | 1.0 | 0.02 | 0.025 | Remainder | X | O | O | O | O |
| Example 10 | | | | | | | | | | | |
| Comparative | 3.0 | 0.7 | 1.0 | 0.12 | 0.025 | Remainder | N | N | X | N | X |
| Example 11 | | | | | | | | | | | |
| Comparative | 3.0 | 0.7 | 1.0 | 0.05 | 0.005 | Remainder | O | X | O | X | O |
| Example 12 | | | | | | | | | | | |
| Comparative | 3.0 | 0.7 | 1.0 | 0.05 | 0.05 | Remainder | O | X | O | X | O |
| Example 13 | | | | | | | | | | | |

Referring to Examples 1 to 15, evaluation criteria for tensile strength, wettability, drop resistance, thermal cycle reliability, and shear strength were all satisfied. On the other hand, the solder alloys of Comparative Examples 1 to 13 did not satisfy at least one of evaluation criteria of tensile strength, wettability, drop resistance, thermal cycle reliability, and shear strength.

Referring to Comparative Example 1, it can be seen that the SAC1205 solder alloy does not satisfy the evaluation criteria for the tensile strength and the wettability. In addition, the viscosity of the SAC1205 solder alloy excessively increases, which makes it impossible to manufacture a solder ball specimen and a semiconductor package specimen.

Referring to Comparative Examples 3, 4, and 10, it can be confirmed that the solder joint made of the solder alloy that does not include Ni or includes Ni in a content of less than 0.03 wt % does not satisfy the evaluation criterion for the drop resistance. The solder alloy that does not include Ni or includes Ni in a content of less than 0.03 wt % may coarsen a crystal size of an IMC layer at an interface. It is regarded that the coarsening of the crystal size of the IMC layer is due to an increase in a ratio of Cu₆Sn₅ to (Ni,Cu)₆Sn₅. As a result, the solder alloy that does not include Ni or includes Ni in a content of less than 0.03 wt % is expected to form a solder joint with degraded drop resistance.

Referring to Comparative Example 11, it can be confirmed that the solder alloy including Ni in a content of more than 0.10 wt % does not satisfy the evaluation criteria for the tensile strength and the wettability. In the solder alloy including Ni in a content of more than 0.10 wt %, Ni-₃Sn4 is precipitated, the viscosity of a molten solder is increased, and a crystal structure is excessively refined, and therefore ductility is expected to degrade. In addition, in the solder alloy including Ni in a content of more than 0.10 wt %, the viscosity of a molten solder excessively increases, which makes it impossible to manufacture a solder ball specimen and a semiconductor package specimen.

Referring to Comparative Examples 6 and 7, it can be confirmed that the solder joint made of the solder alloy including Ag in a content of less than 3.0 wt % does not satisfy the evaluation criterion for the thermal cycle reliability. In the solder joint made of the solder alloy including Ag in a content of less than 3.0 wt %, an amount of precipitated Ag₃Sn is small, and thus it is expected that thermal cycle reliability is not improved.

Referring to Comparative Example 8, it can be confirmed that the solder joint made of the solder alloy including Bi in a content of less than 0.8 wt % does not satisfy the evaluation criterion for the thermal cycle reliability. In the solder joint made of the solder alloy including Bi in a content of less than 0.8 wt %, a solid-solution strengthening effect by Bi is insufficient, and thus the thermal cycle reliability is expected to degrade.

Referring to Comparative Example 9, it can be confirmed that the solder joint made of the solder alloy including Bi in a content of more than 1.2 wt % does not satisfy the evaluation criteria for the drop resistance and the tensile strength. In the solder joint made of the solder alloy including Bi in a content of more than 1.2 wt %, ductility is reduced due to an excessive solid-solution strengthening effect, and thus the drop resistance and the tensile strength are expected to degrade.

Referring to Comparative Examples 2 and 5, it can be confirmed that the solder joint made of the solder alloy that does not includes Pd does not satisfy the evaluation criterion for the thermal cycle reliability. In the solder alloy that does not includes Pd, it is impossible to suppress the formation of Cu₃Sn due to Pd, and thus the thermal cycle reliability of the solder joint is expected to degrade.

Referring to Comparative Example 12, it can be confirmed that the solder joint made of the solder alloy including Pd in a content of less than 0.01 wt % does not satisfy the evaluation criteria for the thermal cycle reliability properties and the shear strength. In the solder alloy including Pd in a content of less than 0.01 wt %, a PdSn₄ formation effect and a Cu₃Sn formation suppressing effect are insignificant, and thus it is expected that there is a limitation in improving the thermal cycle reliability of the solder joint.

Referring to Comparative Example 13, it can be confirmed that the solder joint made of the solder alloy including Pd in a content of more than 0.04 wt % does not satisfy the evaluation criteria for the thermal cycle reliability properties and the shear strength. In the solder alloy including Pd in a content of more than 0.04 wt %, coarse crystals may be formed due to the agglomeration of particles (Ostwald ripening), or an excessive amount of PdSn₄ may be produced, and thus it is expected that the shear strength and thermal cycle reliability of the solder joint are degraded.

Since the solder alloy of one embodiment includes Ag in a content of 2.7 wt % to 3.3 wt %, Cu in a content of 0.50 wt % to 0.75 wt %, Bi in a content of 0.8 wt % to 1.2 wt %, Ni in a content of 0.03 wt % to 010 wt %, Pd in a content of 0.01 wt % to 0.04 wt %, and a remainder of Sn and unavoidable impurities, it can be confirmed that the solder alloy exhibits excellent tensile strength and excellent wettability in a molten state. As a result, the solder joint made of the solder alloy of one embodiment may simultaneously exhibit excellent drop resistance, shear strength, and thermal cycle reliability. Additionally, a semiconductor package including the solder joint of one embodiment may exhibit excellent durability.

Since a solder alloy of one embodiment includes Ag, Cu, Bi, Ni, Pd, and a remainder of Sn in an appropriate composition ratio, the solder alloy can exhibit excellent tensile strength and excellent wettability.

Since a solder joint of one embodiment includes Ag, Cu, Bi, Ni, Pd, and a remainder of Sn in an appropriate composition ratio, the solder joint can exhibit excellent thermal cycle reliability, excellent drop resistance, and excellent shear strength at the same time.

Since a semiconductor package of one embodiment includes a solder joint that simultaneously exhibits excellent thermal cycle reliability and drop resistance, the semiconductor package can exhibit excellent durability.

Although the present invention has been described with reference to embodiments of the present invention, it will be understood by those skilled in the art or those having ordinary knowledge in the art that the present invention may be variously modified and changed without departing from the idea and the technical scope of the present invention described in the claims to be described below. Therefore, the technical scope of the present invention is not limited to the content described in the detailed description of the specification, but should be defined by the claims.

1. A solder alloy comprising:
Ag in a content of 2.7 wt % to 3.3 wt %;
Cu in a content of 0.50 wt % to 0.75 wt %;
Bi in a content of 0.8 wt % to 1.2 wt %;
Ni in a content of 0.03 wt % to 0.10 wt %;
Pd in a content of 0.01 wt % to 0.04 wt %; and
a remainder of Sn and unavoidable impurities.

2. The solder alloy of claim 1, further containing Ge in a content of 0.005 wt % to 0.010 wt %.

3. A solder ball comprising:
Ag in a content of 2.7 wt % to 3.3 wt %;
Cu in a content of 0.50 wt % to 0.75 wt %;
Bi in a content of 0.8 wt % to 1.2 wt %;
Ni in a content of 0.03 wt % to 0.10 wt %;
Pd in a content of 0.01 wt % to 0.04 wt %; and
a remainder of Sn and inevitable impurities.

4. The solder ball of claim 3, further comprising Ge in a content of 0.005 wt % to 0.010 wt %.

5. The solder ball of claim 3, wherein the solder ball has a particle diameter of 10 μm to 780 μm.

6. A semiconductor package comprising:
a lower electronic component;
an upper electronic component disposed on the lower electronic component; and
a solder joint disposed between the lower electronic component and the upper electronic component and made of a solder alloy,
wherein the solder alloy includes:
Ag in a content of 2.7 wt % to 3.3 wt %;
Cu in a content of 0.50 wt % to 0.75 wt %;
Bi in a content of 0.8 wt % to 1.2 wt %;
Ni in a content of 0.03 wt % to 0.10 wt %;
Pd in a content of 0.01 wt % to 0.04 wt %; and
a remainder of Sn and unavoidable impurities.

7. The semiconductor package of claim 6, wherein the lower electronic component includes a substrate and a substrate electrode disposed on the substrate, and
the upper electronic component includes a base layer and a semiconductor electrode disposed on the base layer.

8. The semiconductor package of claim 7, wherein the substrate electrode and the semiconductor electrode include:
an electrode layer including Cu;
a first plating layer disposed on the electrode layer and including Ni; and
a second plating layer disposed on the first plating layer and including Au.
